(19) United States
(12) Patent Application Publication
(10) Pub. No.: US 2026/0082671 A1
(43) Pub. Date: Mar. 19, 2026

(54) SEMICONDUCTOR DEVICE, INVERTER CIRCUIT, DRIVING DEVICE, VEHICLE, AND ELEVATOR

(71) Applicant: KABUSHIKI KAISHA TOSHIBA, Kawasaki-shi (JP)

(72) Inventor: Tatsuo SHIMIZU, Tokyo (JP)

(73) Assignee: KABUSHIKI KAISHA TOSHIBA, Kawasaki-shi (JP)

(21) Appl. No.: 19/311,045

(22) Filed: Aug. 27, 2025

(30) Foreign Application Priority Data
Sep. 18, 2024 (JP) 2024-161108

(51) Int. Cl. H10D 64/68; B60R 16/02; B61C 9/50; B66B 11/04; H02P 27/06; H10D 30/66; H10D 62/832

(52) U.S. Cl. CPC H10D 64/685; H10D 30/66; H10D 62/8325; B60R 16/02; B61C 9/50; B66B 11/043; H02P 27/06

(57) ABSTRACT

A semiconductor device of an embodiment includes a silicon carbide layer, a gate electrode, a silicon oxide layer between the silicon carbide layer and the gate electrode, and containing boron, carbon, and one element of hydrogen, deuterium, and fluorine, and a region provided between the silicon carbide layer and the silicon oxide layer and having a boron concentration equal to or more than 1×10²⁰ cm⁻³. Boron concentration distribution has a peak in the region, a first concentration of boron at a first position 5 nm away from the peak toward the silicon oxide layer, a second concentration of carbon at the first position, and a third concentration of the element at the first position are equal to or more than 1×10¹⁸ cm⁻³. The second concentration is 80% to 120% of the first concentration, and the third concentration is 80% to 120% of the first concentration.

### CROSS-REFERENCE TO RELATED APPLICATION

This application is based upon and claims the benefit of priority from Japanese Patent Application No. 2024-161108, filed on Sep. 18, 2024, the entire contents of which are incorporated herein by reference.

### FIELD

Embodiments described herein relate generally to a semiconductor device, an inverter circuit, a driving device, a vehicle, and an elevator.

### BACKGROUND

Examples of a material for next generation semiconductor devices include silicon carbide (SiC). As compared with silicon (Si), silicon carbide has superior physical properties that a band gap is about three times of that of Si, a breakdown field strength is about ten times of that of Si, and a thermal conductivity is about three times of that of Si. These characteristics are used to achieve a semiconductor device capable of operating with a low loss at high temperature.

For example, when a metal oxide semiconductor field effect transistor (MOSFET) is formed using silicon carbide, there is a problem that carrier mobility decreases or a threshold voltage fluctuates. One factor that causes the decrease in the carrier mobility and the fluctuation in the threshold voltage is considered to be a harmful defect present in a gate insulating layer.

### BRIEF DESCRIPTION OF THE DRAWINGS

FIG. 1 is a schematic cross-sectional view of a semiconductor device of a first embodiment;

FIG. 2 is a view illustrating a crystal structure of a SiC semiconductor;

FIG. 3 is a graph illustrating element concentration distributions of the semiconductor device of the first embodiment;

FIG. 4 is a schematic view illustrating a bonding state of a boron atom of the semiconductor device of the first embodiment;

FIG. 5 is an explanatory view of a gate insulating layer of the semiconductor device of the first embodiment;

FIG. 6 is an explanatory view of the gate insulating layer of the semiconductor device of the first embodiment;

FIGS. 7A, 7B, and 7C are explanatory views of a function and an effect of the semiconductor device of the first embodiment;

FIG. 8 is an explanatory view of the function and the effect of the semiconductor device of the first embodiment;

FIGS. 9A, 9B, and 9C are explanatory views of the function and the effect of the semiconductor device of the first embodiment;

FIG. 10 is a graph illustrating element concentration distributions of a semiconductor device of a modified example of the first embodiment;

FIG. 11 is a schematic cross-sectional view of a semiconductor device of a second embodiment;

FIG. 12 is a graph illustrating element concentration distributions of the semiconductor device of the second embodiment;

FIG. 13 is a schematic view of a driving device of a third embodiment;

FIG. 14 is a schematic view of a vehicle of a fourth embodiment;

FIG. 15 is a schematic view of a vehicle of a fifth embodiment; and

FIG. 16 is a schematic view of an elevator of a sixth embodiment.

### DETAILED DESCRIPTION

A semiconductor device of an embodiment includes a silicon carbide layer, a gate electrode, a silicon oxide layer provided between the silicon carbide layer and the gate electrode and containing one element selected from the group consisting of hydrogen (H), deuterium (D), and fluorine (F), boron (B), and carbon (C), and a region provided between the silicon carbide layer and the silicon oxide layer and having a boron concentration equal to or more than 1×10²⁰ cm⁻³, in which a boron concentration distribution in the silicon carbide layer, the silicon oxide layer, and the region has a first peak in the region, a first concentration of boron at a first position 5 nm away from the first peak toward the silicon oxide layer is equal to or more than 1×10¹⁸ cm⁻³, a second concentration of carbon at the first position is equal to or more than 1×10¹⁸ cm⁻³, a third concentration of the element at the first position is equal to or more than 1×10¹⁸ cm⁻³, the second concentration is 80% or more and 120% or less of the first concentration, and the third concentration is 80% or more and 120% or less of the first concentration.

Hereinafter, embodiments of the present disclosure will be described with reference to the drawings. In the following description, the same or equivalent members and the like will be denoted by the same reference numerals, and members that have been once described will not be described as appropriate.

In the following description, notations n⁺, n, n⁻, p⁺, p, and p⁻ indicate relative levels of impurity concentration in each conductivity type. That is, n⁺ indicates an n-type impurity concentration higher than that of n, and n⁻ indicates an n-type impurity concentration lower than that of n. In addition, p⁺ indicates a p-type impurity concentration higher than that of p, and p⁻ indicates a p-type impurity concentration lower than that of p. In some cases, an n⁺-type and an n⁻ type are simply referred to as an n-type, and a p⁺-type and a p⁻ type are simply referred to as a p-type. Unless otherwise specified, the impurity concentration of each region is represented by, for example, a value of an impurity concentration at the center of each region.

The impurity concentration can be measured by secondary ion mass spectrometry (SIMS), for example. In addition, a relative level of the impurity concentration can also be determined based on a level of a carrier concentration obtained by, for example, scanning capacitance microscopy (SCM). In addition, a distance such as a width and a depth of an impurity region can be obtained by SIMS, for example. In addition, a distance such as a width and a depth of an impurity region can be obtained from an SCM image, for example.

The concentration of a silicon atom, a carbon atom, a boron atom, an oxygen atom, a hydrogen atom, a deuterium atom, or a fluorine atom in a silicon carbide layer or a gate insulating layer can be measured by SIMS.

In the present specification, the impurity concentration and the concentration of each element are represented by atomic concentrations.

A depth of a trench, a thickness of an insulating layer, and the like can be measured on an image of SIMS or a transmission electron microscope (TEM), for example.

Bonding states of silicon atoms, carbon atoms, boron atoms, oxygen atoms, hydrogen atoms, deuterium atoms, or fluorine atoms in the silicon carbide layer or the gate insulating layer can be identified by using, for example, X-ray photoelectron spectroscopy (XPS method) or Fourier transform infrared spectroscopy (FT-IR method). In addition, concentrations of various bonding states and the magnitude relationship of the concentrations can be determined by using, for example, X-ray photoelectron spectroscopy or Fourier transform infrared spectroscopy.

### FIRST EMBODIMENT

A semiconductor device of a first embodiment includes a silicon carbide layer, a gate electrode, a silicon oxide layer provided between the silicon carbide layer and the gate electrode and containing one element selected from the group consisting of hydrogen (H), deuterium (D), and fluorine (F), boron (B), and carbon (C), and a region provided between the silicon carbide layer and the silicon oxide layer and having a boron concentration equal to or more than 1×10²⁰ cm⁻³. A boron concentration distribution in the silicon carbide layer, the silicon oxide layer, and the region has a first peak in the region, a first concentration of boron at a first position 5 nm away from the first peak toward the silicon oxide layer is equal to or more than 1×10¹⁸ cm⁻³, a second concentration of carbon at the first position is equal to or more than 1×10¹⁸ cm⁻³, a third concentration of the element at the first position is equal to or more than 1×10¹⁸ cm⁻³, the second concentration is 80% or more and 120% or less of the first concentration, and the third concentration is 80% or more and 120% or less of the first concentration.

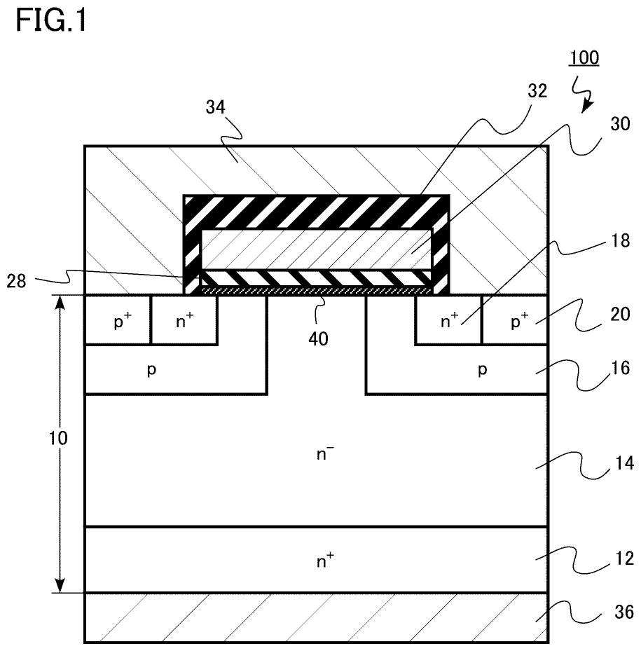

FIG. 1 is a schematic cross-sectional view of the semiconductor device of the first embodiment. The semiconductor device is a MOSFET 100. The MOSFET 100 is a double implantation MOSFET (DIMOSFET) in which a p-well and a source region are formed by ion implantation. In addition, the MOSFET 100 is an n-channel MOSFET using electrons as carriers.

The MOSFET 100 includes a silicon carbide layer 10, a gate insulating layer 28 (silicon oxide layer), a gate electrode 30, an interlayer insulating film 32, a source electrode 34, a drain electrode 36, and an interface termination region 40 (region).

The silicon carbide layer 10 includes a drain region 12, a drift region 14, a p-well region 16, a source region 18, and a p-well contact region 20.

The silicon carbide layer 10 is a single crystal of, for example, 4H-SiC. The silicon carbide layer 10 is disposed between the source electrode 34 and the drain electrode 36.

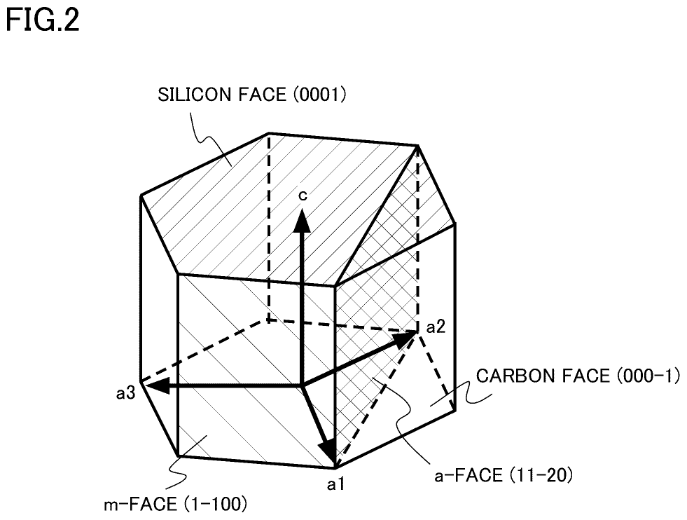

FIG. 2 is a view illustrating a crystal structure of a SiC semiconductor. A typical crystal structure of the SiC semiconductor is a hexagonal crystal system such as 4H-SiC. One of faces (bases of a hexagonal prism) whose normal line is a c-axis along the axial direction of the hexagonal prism is a (0001) face. A face equivalent to the (0001) face is referred to as a silicon face (Si face) and denoted as a {0001} face. Silicon atoms (Si) are arranged on the outermost surface of the silicon face.

The other of the faces (bases of the hexagonal prism) whose normal line is the c-axis along the axial direction of the hexagonal prism is a (000-1) face. A face equivalent to the (000-1) face is referred to as a carbon face (C face) and denoted as a {000-1} face. Carbon atoms (C) are arranged on the outermost surface of the carbon face.

On the other hand, a side face (prism face) of the hexagonal prism is an m-face which is a face equivalent to a (1-100) face, that is, a {1-100} face. In addition, a face passing through a pair of ridgelines not adjacent to each other is an a-face which is a face equivalent to a (11-20) face, that is, a {11-20} face. Both the silicon atoms (Si) and the carbon atoms (C) are arranged on the outermost surfaces of the m-face and the a-face.

Hereinafter, a description will be given by exemplifying a case where a surface and a back surface of the silicon carbide layer 10 are a face inclined by 0° or more and 8° or less with respect to the silicon face and a face inclined by 0° or more and 8° or less with respect to the carbon face, respectively. The surface of the silicon carbide layer 10 has an off-angle of 0° or more and 8° or less with respect to the silicon face.

The drain region 12 is n⁺-type SiC. The drain region 12 contains, for example, nitrogen (N) as an n-type impurity. An n-type impurity concentration of the drain region 12 is, for example, 1×10¹⁸ cm⁻³ or more and 1×10²¹ cm⁻³ or less.

The drift region 14 is provided on the drain region 12. The drift region 14 is n⁻ type SiC. The drift region 14 contains, for example, nitrogen (N) as an n-type impurity.

An n-type impurity concentration of the drift region 14 is lower than the n-type impurity concentration of the drain region 12. The n-type impurity concentration of the drift region 14 is, for example, 1×10¹⁵ cm⁻³ or more and 2×10¹⁶ cm⁻³ or less. The drift region 14 is, for example, an SiC epitaxial growth layer formed on the drain region 12 by epitaxial growth.

A thickness of the drift region 14 is, for example, 5 μm or more and 100 μm or less.

The p-well region 16 is provided on a partial surface of the drift region 14. The p-well region 16 is p-type SiC. The p-well region 16 contains, for example, aluminum (Al) as a p-type impurity. A p-type impurity concentration of the p-well region 16 is, for example, 1×10¹⁶ cm⁻³ or more and 1×10²⁰ cm⁻³ or less.

A depth of the p-well region 16 is, for example, 0.4 μm or more and 0.8 μm or less. The p-well region 16 functions as a channel region of the MOSFET 100.

The source region 18 is provided on a partial surface of the p-well region 16. The source region 18 is n⁺-type SiC. The source region 18 contains, for example, phosphorus (P) as an n-type impurity. An n-type impurity concentration of the source region 18 is, for example, 1×10¹⁸ cm⁻³ or more and 1×10²² cm⁻³ or less.

A depth of the source region 18 is shallower than the depth of the p-well region 16. The depth of the source region 18 is, for example, 0.2 μm or more and 0.4 μm or less.

The p-well contact region 20 is provided on a partial surface of the p-well region 16. The p-well contact region 20 is provided next to the source region 18. The p-well contact region 20 is p⁺-type SiC.

The p-well contact region 20 contains, for example, aluminum as a p-type impurity. A p-type impurity concentration of the p-well contact region 20 is, for example, 1×10¹⁸ cm⁻³ or more and 1×10²² cm⁻³ or less.

A depth of the p-well contact region 20 is shallower than the depth of the p-well region 16. The depth of the p-well contact region 20 is, for example, 0.2 μm or more and 0.4 μm or less

The gate insulating layer 28 is provided between the silicon carbide layer 10 and the gate electrode 30. The gate insulating layer 28 is provided between the drift region 14 and the p-well region 16, and the gate electrode 30. The gate insulating layer 28 is provided on the drift region 14 and the p-well region 16. The gate insulating layer 28 is continuously formed on surfaces of the drift region 14 and the p-well region 16.

The gate insulating layer 28 is silicon oxide. The gate insulating layer 28 is, for example, silicon dioxide. The gate insulating layer 28 is an example of a silicon oxide layer.

The gate insulating layer 28 contains one element selected from the group consisting of hydrogen (H), deuterium (D), and fluorine (F), boron (B), and carbon (C). Hereinafter, hydrogen (H) will be described as an example of one element.

A thickness of the gate insulating layer 28 is, for example, 30 nm or more and 100 nm or less. The gate insulating layer 28 functions as a gate insulating layer of the MOSFET 100. The thickness of the gate insulating layer 28 is, for example, 40 nm or more and 50 nm or less.

The interface termination region 40 is disposed between the silicon carbide layer 10 and the gate insulating layer 28. The interface termination region 40 is disposed between the drift region 14 and the p-well region 16, and the gate insulating layer 28. The interface termination region 40 contains boron (B) as a termination element that terminates a dangling bond of the silicon carbide layer 10. The interface termination region 40 is an example of a region.

A boron concentration in the interface termination region 40 is equal to or more than 1×10²⁰ cm⁻³.

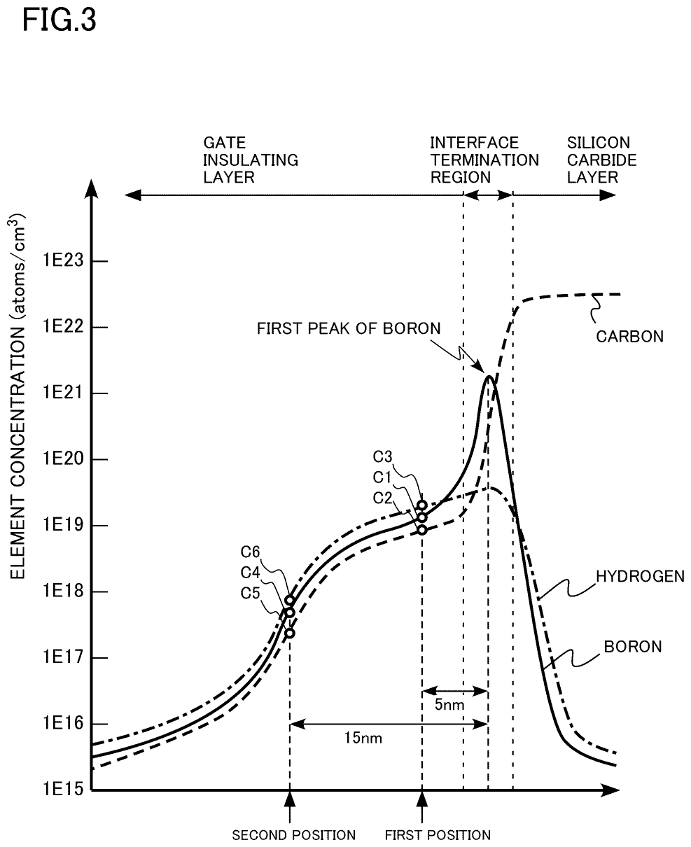

FIG. 3 is a graph illustrating element concentration distributions of the semiconductor device of the first embodiment. FIG. 3 is a graph illustrating element concentration distributions in the gate insulating layer 28, the interface termination region 40, and the silicon carbide layer 10.

FIG. 3 illustrates concentration distributions of boron (B), carbon (C), and hydrogen (H). In FIG. 3, a solid line indicates the boron concentration distribution, a dotted line indicates the carbon concentration distribution, and an alternate long and short dash line indicates the hydrogen concentration distribution.

The boron concentration distribution has a first peak in the interface termination region 40. The boron concentration at the first peak is, for example, 1×10²⁰ cm⁻³ or more and 1×10²² cm⁻³ or less. A full width at half maximum for the first peak of the boron concentration distribution is, for example, 1 nm or less. Boron is segregated at an interface between the silicon carbide layer 10 and the gate insulating layer 28.

A hydrogen concentration in the interface termination region 40 is lower than the boron concentration in the interface termination region 40, for example. The hydrogen concentration in the interface termination region 40 is, for example, 1×10²⁰ cm⁻³ or less.

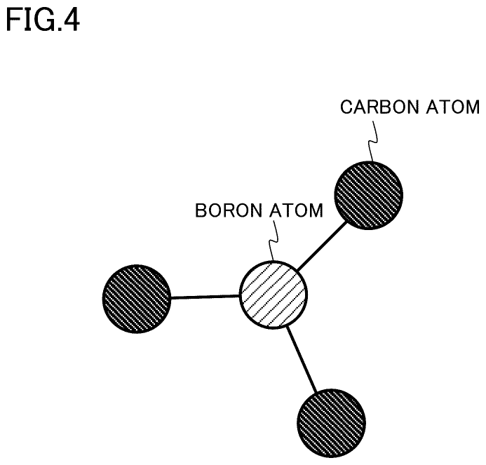

FIG. 4 is a schematic view illustrating a bonding state of a boron atom of the semiconductor device of the first embodiment. FIG. 4 illustrates a bonding state of a boron atom in the interface termination region 40. FIG. 4 illustrates a case where a boron atom is bonded to three carbon atoms.

The interface termination region 40 contains tricoordinate boron atoms. The interface termination region 40 contains boron atoms each of which is bonded to three carbon atoms.

The tricoordinate boron atoms present in the interface termination region 40 terminate the dangling bond on the surface of the silicon carbide layer 10. The boron atom substitutes for a silicon atom on the outermost surface of the silicon carbide layer 10.

As illustrated in FIG. 3, for example, a first concentration (C1 in FIG. 3) of boron at a first position 5 nm away from the first peak of the boron concentration distribution toward the gate insulating layer 28 is 1×10¹⁸ cm⁻³ or more and 1×10²¹ cm⁻³ or less. In addition, for example, a second concentration (C2 in FIG. 3) of carbon at the first position is 1×10¹⁸ cm⁻³ or more and 1×10²¹ cm⁻³ or less. In addition, for example, a third concentration (C3 in FIG. 3) of hydrogen at the first position is 1×10¹⁸ cm⁻³ or more and 1×10²¹ cm⁻³ or less.

For example, the first concentration C1 is 1×10¹⁹ cm⁻³ or more and 1×10²⁰ cm⁻³ or less, the second concentration C2 is 1×10¹⁹ cm⁻³ or more and 1×10²⁰ cm⁻³ or less, and the third concentration C3 is 1×10¹⁹ cm⁻³ or more and 1×10²⁰ cm⁻³ or less.

The second concentration C2 is 80% or more and 120% or less of the first concentration C1. In addition, the third concentration C3 is 80% or more and 120% or less of the first concentration C1.

For example, the second concentration C2 is 90% or more and 110% or less of the first concentration C1. In addition, for example, the third concentration C3 is 90% or more and 110% or less of the first concentration C1.

As illustrated in FIG. 3, for example, a fourth concentration (C4 in FIG. 3) of boron at a second position 15 nm away from the first peak of the boron concentration distribution toward the gate insulating layer 28 is 1×10¹⁷ cm⁻³ or more and 1×10²⁰ cm⁻³ or less. In addition, for example, a fifth concentration (C5 in FIG. 3) of carbon at the second position is 1×10¹⁷ cm⁻³ or more and 1×10²⁰ cm⁻³ or less. In addition, for example, a sixth concentration (C6 in FIG. 3) of hydrogen at the second position is 1×10¹⁷ cm⁻³ or more and 1×10²⁰ cm⁻³ or less.

For example, the fifth concentration C5 is 80% or more and 120% or less of the fourth concentration C4. In addition, for example, the sixth concentration C6 is 80% or more and 120% or less of the fourth concentration C4.

For example, the fifth concentration C5 is 90% or more and 110% or less of the fourth concentration C4. In addition, for example, the sixth concentration C6 is 90% or more and 110% or less of the fourth concentration C4.

The concentration distributions of boron, carbon, and hydrogen can be favorably matched with each other by a method for manufacturing the semiconductor device of the first embodiment to be described later. If precise concentration measurement below the measurement limit of the SIMS measurement is required, it is effective to use hard X-ray photoelectron spectroscopy (HAXPES) measurement or the like.

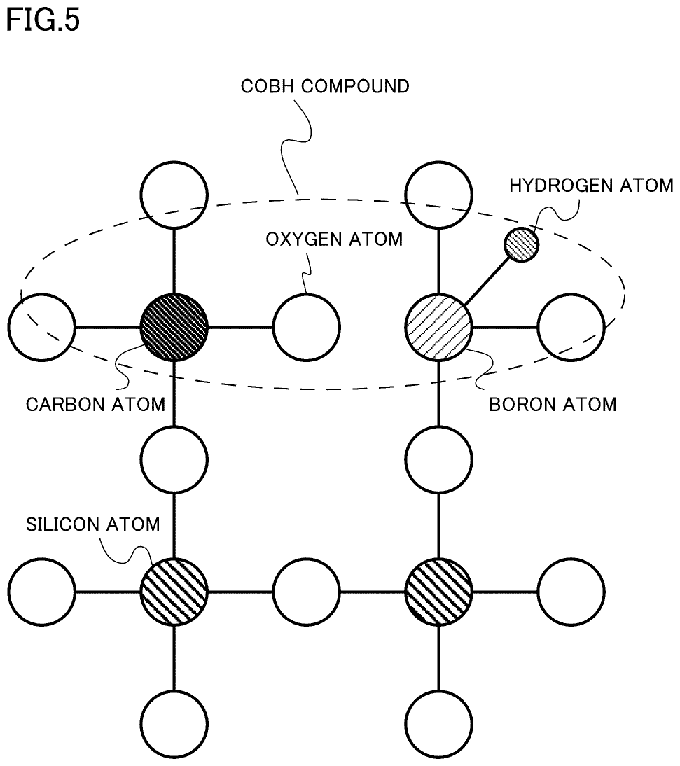

FIG. 5 is an explanatory view of the gate insulating layer of the semiconductor device of the first embodiment. FIG. 5 illustrates a compound including a carbon atom, oxygen atoms, a boron atom, and a hydrogen atom contained in the gate insulating layer 28. Hereinafter, the compound including the carbon atom, the oxygen atoms, the boron atom, and the hydrogen atom illustrated in FIG. 5 is referred to as a COBH compound.

As illustrated in FIG. 5, in the COBH compound, the carbon atom, the oxygen atoms, the boron atom, and the hydrogen atom are close to each other in silicon oxide to form the compound. In the COBH compound, the carbon atom and the oxygen atom are bonded to each other, the boron atom and the oxygen atom are bonded to each other, and the boron atom and the hydrogen atom are bonded to each other.

In the COBH compound, each of the carbon atom and the boron atom substitutes for a silicon atom of the silicon oxide. In other words, in the COBH compound, each of the carbon atom and the boron atom is present at a silicon site of silicon dioxide. In the COBH compound, the oxygen atom is present between the carbon atom and the boron atom. The oxygen atom between the carbon atom and the boron atom and the boron atom are not covalently bonded. The carbon atom and the oxygen atom are bonded by a single bond, the boron atom and the oxygen atom are bonded by a single bond, and the boron atom and the hydrogen atom are bonded by a single bond. The carbon atom constituting the COBH compound is tetracoordinated. The boron atom constituting the COBH compound is tetracoordinated.

In the COBH compound, for example, the tetracoordinate carbon atom is positively charged. In addition, in the COBH compound, for example, the tetracoordinate boron atom is negatively charged.

The gate insulating layer 28 contains the COBH compounds, and thus contains boron atoms each of which is bonded to three oxygen atoms and one hydrogen atom.

For example, most of carbon atoms, boron atoms, and hydrogen atoms present in a region 5 nm or more away from the peak of the boron concentration distribution toward the gate insulating layer 28 constitute the COBH compounds. Therefore, for example, as illustrated in FIG. 3, a distribution of the carbon atoms, a distribution of the boron atoms, and a distribution of the hydrogen atoms overlap in the region 5 nm or more away from the peak of the boron concentration distribution toward the gate insulating layer 28.

For example, as the distance from the peak of the boron concentration distribution increases, an amount of the COBH compounds in the gate insulating layer 28 decreases. Therefore, as illustrated in FIG. 3, the concentration of carbon, the concentration of boron, and the concentration of hydrogen in the gate insulating layer 28 decrease as the distance from the peak of the boron concentration distribution increases.

Since most of hydrogen atoms in the gate insulating layer 28 constitute the COBH compounds, an amount of hydrogen atoms bonded to boron atoms in the gate insulating layer 28 is larger than an amount of hydrogen atoms bonded to silicon atoms.

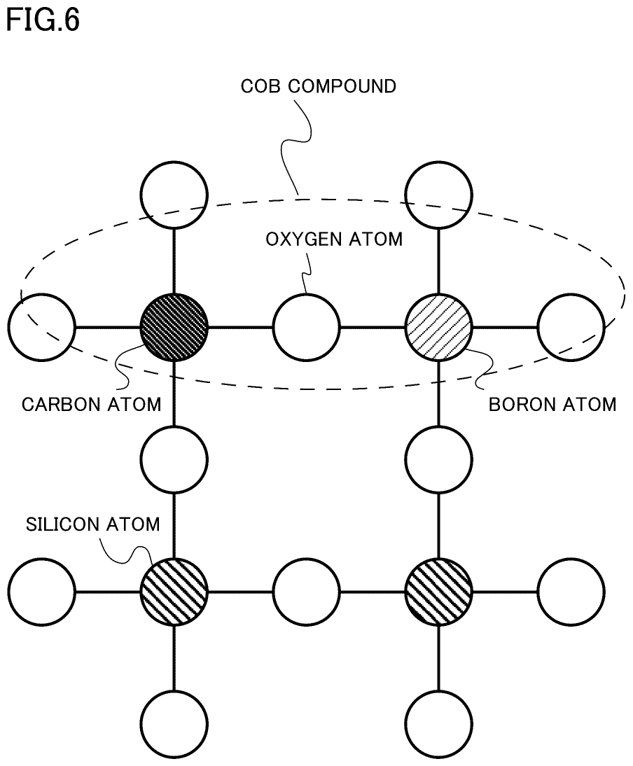

FIG. 6 is an explanatory view of the gate insulating layer of the semiconductor device of the first embodiment. FIG. 6 illustrates a compound that is likely to be contained in the gate insulating layer 28 and includes a carbon atom, oxygen atoms, and a boron atom. Hereinafter, the compound including the carbon atom, the oxygen atoms, and the boron atom illustrated in FIG. 6 is referred to as a COB compound. In some cases, the COB compound is not included in the gate insulating layer 28.

As illustrated in FIG. 6, in the COB compound, the carbon atom, the oxygen atoms, and the boron atom are close to each other in silicon oxide to form the compound. In the COB compound, the carbon atom and the oxygen atom are bonded to each other, and the oxygen atom and the boron atom are bonded to each other.

In the COB compound, each of the carbon atom and the boron atom substitutes for a silicon atom of the silicon oxide. In other words, in the COB compound, each of the carbon atom and the boron atom is present at a silicon site of silicon dioxide. In the COB compound, the oxygen atom is present between the carbon atom and the boron atom. The carbon atom and the oxygen atom are bonded by a single bond, and the oxygen atom and the boron atom are bonded by a single bond. The carbon atom constituting the COB compound is tetracoordinated. The boron atom constituting the COB compound is tetracoordinated. The boron atom constituting the COB compound is bonded to four oxygen atoms.

In the COB compound, for example, the tetracoordinate carbon atom is not charged. In addition, in the COB compound, for example, the tetracoordinate boron atom is not charged.

When the gate insulating layer 28 includes the COB compound, an amount of the COBH compound is larger than an amount of the COB compound in the gate insulating layer 28. Therefore, in the gate insulating layer 28, an amount of boron atoms each being bonded to three oxygen atoms and one hydrogen atom is larger than an amount of boron atoms each being bonded to four oxygen atoms. In the gate insulating layer 28, the amount of boron atoms each being bonded to three oxygen atoms and one hydrogen atom is, for example, ten times or more the amount of boron atoms each being bonded to four oxygen atoms.

The gate electrode 30 is provided on the gate insulating layer 28. The gate electrode 30 sandwiches the gate insulating layer 28 with the silicon carbide layer 10. The gate electrode 30 sandwiches the gate insulating layer 28 with the drift region 14. The gate electrode 30 sandwiches the gate insulating layer 28 with the p-well region 16.

The gate electrode 30 is, for example, polycrystalline silicon containing an n-type impurity or a p-type impurity.

The interlayer insulating film 32 is formed on the gate electrode 30. The interlayer insulating film 32 is, for example, a silicon oxide film.

The source electrode 34 is electrically connected to the source region 18 and the p-well contact region 20. The source electrode 34 also functions as a p-well electrode that applies an electric potential to the p-well region 16.

The source electrode 34 is formed by, for example, stacking a barrier metal layer of nickel (Ni) and a metal layer of aluminum on the barrier metal layer. The barrier metal layer of nickel and the silicon carbide layer may react to form nickel silicide (NiSi, Ni₂Si, or the like). The barrier metal layer of nickel and the metal layer of aluminum may form an alloy by reaction.

The drain electrode 36 is provided on the silicon carbide layer 10 on the side opposite to the source electrode 34, that is, on the back surface side. The drain electrode 36 is, for example, nickel. Nickel may react to the drain region 12 to form nickel silicide (NiSi, Ni₂Si, or the like).

In the first embodiment, the n-type impurity is, for example, nitrogen or phosphorus. Arsenic (As) or antimony (Sb) can also be applied as the n-type impurity.

In the first embodiment, the p-type impurity is, for example, aluminum. Boron (B), gallium (Ga), or indium (In) can also be applied as the p-type impurity.

Next, an example of the method for manufacturing the semiconductor device of the first embodiment will be described.

First, the silicon carbide layer 10 is prepared. The silicon carbide layer 10 includes the drain region 12 of the n⁺-type and the drift region 14 of the n⁻type. The drift region 14 is formed, for example, on the drain region 12 by an epitaxial growth method.

The drain region 12 contains nitrogen as an n-type impurity. An n-type impurity concentration of the drain region 12 is, for example, 1×10¹⁸ cm⁻³ or more and 1×10²¹ cm⁻³ or less.

The drift region 14 contains nitrogen as an n-type impurity. The n-type impurity concentration of the drift region 14 is, for example, 1×10¹⁵ cm⁻³ or more and 2×10¹⁶ cm⁻³ or less. A thickness of the drift region 14 is, for example, 5 μm or more and 100 μm or less.

First, a first mask material is formed by patterning using photolithography and etching. Then, aluminum as a p-type impurity is ion-implanted into the drift region 14 using the first mask material as an ion implantation mask. The p-well region 16 is formed by ion implantation.

Next, a second mask material is formed by patterning using photolithography and etching. Then, phosphorus as an n-type impurity is ion-implanted into the drift region 14 to form the source region 18 using the second mask material as an ion implantation mask.

Next, a third mask material is formed by patterning using photolithography and etching. Aluminum as a p-type impurity is ion-implanted into the drift region 14 to form the p-well contact region 20 using the third mask material as an ion implantation mask.

Next, a polycrystalline silicon film containing boron is formed on the silicon carbide layer 10. A thickness of the polycrystalline silicon film is, for example, 5 nm or more and 50 nm or less.

The polycrystalline silicon film is formed by, for example, vapor phase growth. The polycrystalline silicon film is formed by, for example, a chemical vapor deposition method (CVD method).

Next, a first heat treatment is performed. The first heat treatment is performed in an oxidizing atmosphere. For example, oxygen gas (O₂) diluted with nitrogen gas (N₂) is supplied to a reaction furnace containing the silicon carbide layer 10 to perform the heat treatment. The temperature of the first heat treatment is 900° C. or higher and 1300° C. or lower.

By the first heat treatment, the polycrystalline silicon film is oxidized to form a silicon oxide film containing boron. A thickness of the silicon oxide film containing boron is, for example, 10 nm or more and 100 nm or less. The silicon oxide film containing boron serves as the gate insulating layer 28.

The interface termination region 40 is formed at an interface between the silicon carbide layer 10 and the silicon oxide film by the first heat treatment.

By the first heat treatment, the surface of the silicon carbide layer 10 is oxidized, and excess carbon diffuses into the silicon oxide film.

Next, a second heat treatment is performed. The second heat treatment is performed in an atmosphere containing 20% or more and 60% or less of hydrogen gas (H₂). The hydrogen gas (H₂) is diluted with, for example, nitrogen gas (N₂) or argon gas (Ar).

For example, the hydrogen gas (H₂) diluted with the nitrogen gas (N₂) is supplied to a reaction furnace containing the silicon carbide layer 10 to perform the heat treatment. The temperature of the second heat treatment is 600° C. or higher and 900° C. or lower.

The COBH compounds are formed in the silicon oxide film containing boron by the second heat treatment.

Next, the gate electrode 30 is formed on the gate insulating layer 28. The gate electrode 30 is, for example, polycrystalline silicon containing an n-type impurity or a p-type impurity.

After the second heat treatment and before the formation of the gate electrode 30, for example, a silicon oxide film may be formed on the gate insulating layer 28 by a CVD method.

Next, the interlayer insulating film 32 is formed on the gate electrode 30. The interlayer insulating film 32 is, for example, a silicon oxide film.

Next, the source electrode 34 is formed. The source electrode 34 is formed on the source region 18 and the p-well contact region 20. The source electrode 34 is formed by sputtering of nickel (Ni) and aluminum (Al), for example.

Next, the drain electrode 36 is formed. The drain electrode 36 is formed on the back surface side of the silicon carbide layer 10. The drain electrode 36 is formed by, for example, sputtering of nickel.

The MOSFET 100 illustrated in FIG. 1 is manufactured according to the above manufacturing method.

Next, a function and an effect of the semiconductor device of the first embodiment will be described.

When a MOSFET is formed using silicon carbide, there is a problem that carrier mobility decreases. One factor that decreases the carrier mobility is considered to be an interface state between a silicon carbide layer and a gate insulating layer. The interface state is considered to be generated by dangling bonds present on a surface of the silicon carbide layer.

The MOSFET 100 of the first embodiment includes the interface termination region 40 in which boron is segregated between the silicon carbide layer 10 and the gate insulating layer 28. The dangling bonds are reduced by the interface termination region 40. Therefore, the MOSFET 100 in which the decrease in the carrier mobility is suppressed is achieved.

In addition, when a MOSFET is formed using silicon carbide, there is a problem that carrier mobility decreases or a threshold voltage fluctuates. In addition, there is a problem that a leakage current of a gate insulating layer increases or reliability of the gate insulating layer decreases. One factor that causes the above problems is considered to be a harmful defect present in the gate insulating layer.

The harmful defect present in the gate insulating layer is considered to be, for example, oxygen deficiency in silicon oxide or a defect caused by carbon contained in silicon oxide. The defect present in the gate insulating layer forms a trap state in the gate insulating layer, and thus is considered to be a factor that causes the above problems.

In the MOSFET 100 of the first embodiment, an amount of harmful defects in the gate insulating layer 28 is reduced. Therefore, the decrease in the carrier mobility, the fluctuation in the threshold voltage, the increase in the leakage current of the gate insulating layer, or the decrease in the reliability of the gate insulating layer due to the harmful defects is suppressed. Details will be described hereinafter.

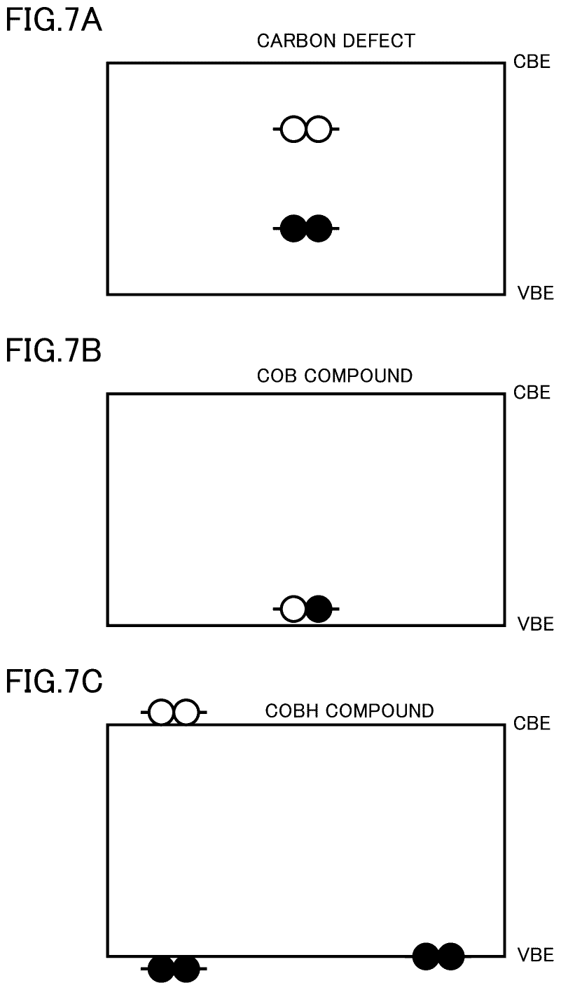

FIGS. 7A, 7B, and 7C are explanatory views of the function and the effect of the semiconductor device of the first embodiment. FIGS. 7A, 7B, and 7C are band diagrams of silicon dioxide. A valence band upper end (VBE) and a conduction band lower end (CBE) of the silicon dioxide are illustrated in each of FIGS. 7A, 7B, and 7C.

FIG. 7A illustrates a case where carbon defects are present in the gate insulating layer of silicon dioxide, FIG. 7B illustrates a case where the COB compound is present in the gate insulating layer of silicon dioxide, and FIG. 7C illustrates a case where the COBH compound is present in the gate insulating layer of silicon dioxide.

In the gate insulating layer, a large number of carbon defects resulting from carbon released into the gate insulating layer by oxidation of the silicon carbide layer are formed. As illustrated in FIG. 7A, when the carbon defects are present in the gate insulating layer, trap states are formed in the gate insulating layer. Examples of the carbon defects include a double-bonded carbon and a carbon double-bonded to oxygen.

When boron (B) is contained in the gate insulating layer, carbon released into the gate insulating layer is bonded to boron to form the COB compound. Therefore, the formation of the carbon defects in the gate insulating layer is suppressed. As the formation of the carbon defects is suppressed, the decrease in the reliability of the gate insulating layer is suppressed.

However, when the COB compound is formed, for example, the fluctuation in the threshold voltage or negative bias temperature instability (NBTI) occurs when AC stress is applied to the gate insulating layer.

As illustrated in FIG. 7B, when the COB compound is formed, the trap state is formed near the valence band upper end (VBE). It is considered that holes are trapped at the trap state near the valence band upper end, thereby causing the fluctuation in the threshold voltage and the NBTI at the time of AC stress.

In the MOSFET 100 of the first embodiment, the gate insulating layer includes the COBH compound. As illustrated in FIG. 7C, in the COBH compound, no trap state is formed in the gate insulating layer. In the MOSFET 100 of the first embodiment, the COB compound in the gate insulating layer is converted into the COBH compound.

Therefore, in the MOSFET 100, the fluctuation in the threshold voltage and the NBTI at the time of AC stress are suppressed. Therefore, the reliability of the MOSFET 100 is also improved.

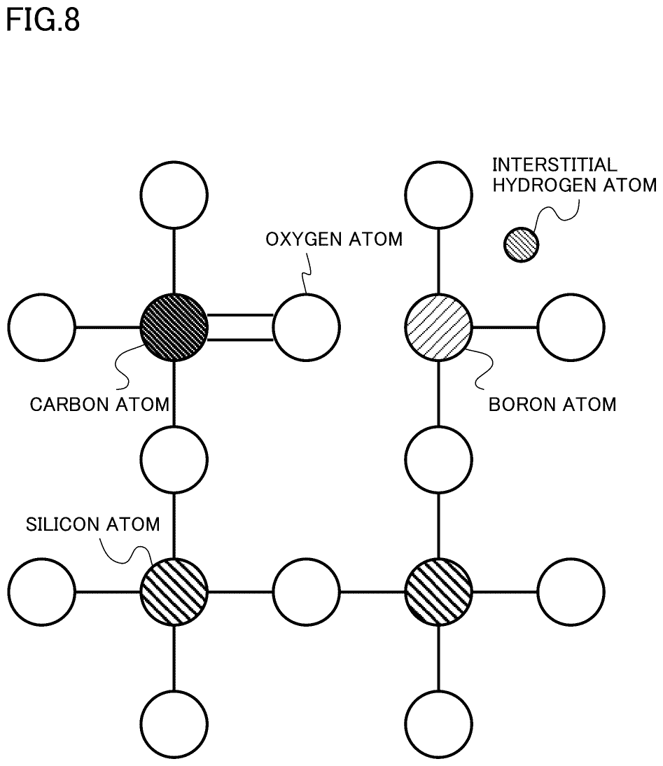

FIG. 8 is an explanatory view of the function and the effect of the semiconductor device of the first embodiment. FIG. 8 is a view illustrating a structure of a transient state when the COB compound is converted into the COBH compound.

When hydrogen gas is introduced into the gate insulating layer in which the COB compound illustrated in FIG. 6 is present, a state is formed as illustrated in FIG. 8 in which a carbon atom is transiently double-bonded to an oxygen atom, a boron atom is tricoordinated, and a hydrogen atom is present between lattices. Thereafter, the COBH compound illustrated in FIG. 5, which is more stable in terms of energy than the structure of FIG. 8, is formed.

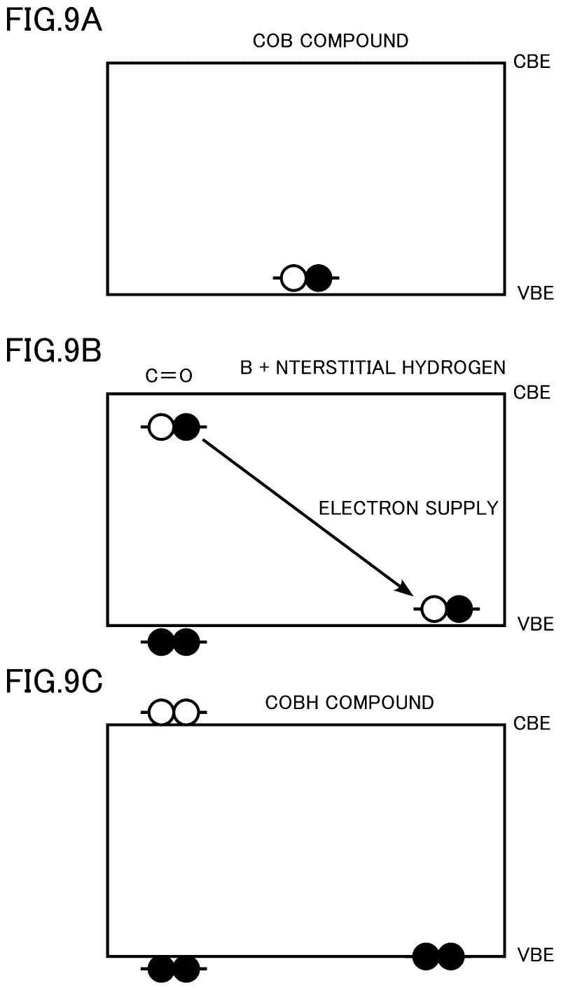

FIGS. 9A, 9B, and 9C are explanatory views of the function and the effect of the semiconductor device of the first embodiment. FIGS. 9A, 9B, and 9C are band diagrams of silicon dioxide. A valence band upper end (VBE) and a conduction band lower end (CBE) of the silicon dioxide are illustrated in each of FIGS. 9A, 9B, and 9C. FIGS. 9A, 9B, and 9C are explanatory views of a state change when the COB compound is converted into the COBH compound.

FIGS. 9A, 9B, and 9C are based on a result of first principle calculation of the inventor.

When hydrogen gas is introduced into the gate insulating layer containing the COB compound illustrated in FIG. 9A, a state is formed as illustrated in FIG. 9B in which a carbon atom is transiently double-bonded to an oxygen atom as illustrated in FIG. 9B, a boron atom is tricoordinated, and a hydrogen atom is present between lattices. It is considered that an electron is supplied to the boron atom from the double bond between the carbon atom and the oxygen atom in the state illustrated in FIG. 9B, and the boron atom becomes a tetracoordinate boron atom bonded to three oxygen atoms and one hydrogen atom, and is stabilized. That is, the COBH compound illustrated in FIG. 9C is formed and stabilized.

In the MOSFET 100 of the first embodiment, most of carbon atoms, boron atoms, and hydrogen atoms contained in the gate insulating layer 28 are fixed as the COBH compounds which are defects harmless to the characteristics of the MOSFET 100. In other words, the amount of the carbon defects and the COB compounds, which are defects harmful to the characteristics of the MOSFET 100, is extremely small in the gate insulating layer 28 of the MOSFET 100. In the MOSFET 100, since the amount of the harmful defects in the gate insulating layer 28 is reduced, the decrease in the carrier mobility or the fluctuation in the threshold voltage can be suppressed.

In the MOSFET 100 of the first embodiment, for example, when AC stress of −5 MV/cm to 5 MV/cm at 1 MHz is applied between the silicon carbide layer 10 and the gate electrode 30 at room temperature for 100 hours, the fluctuation in the threshold voltage is less than 0.1 V.

### Modified Example

A semiconductor device of a modified example of the first embodiment is different from the semiconductor device according to the first embodiment in that a fourth concentration of boron at a second position 15 nm away from a first peak toward a silicon oxide layer is less than 1×10¹⁷ cm⁻³, a fifth concentration of carbon at the second position is less than 1×10¹⁷ cm⁻³, and a sixth concentration of an element at the second position is less than 1×10¹⁷ cm⁻³.

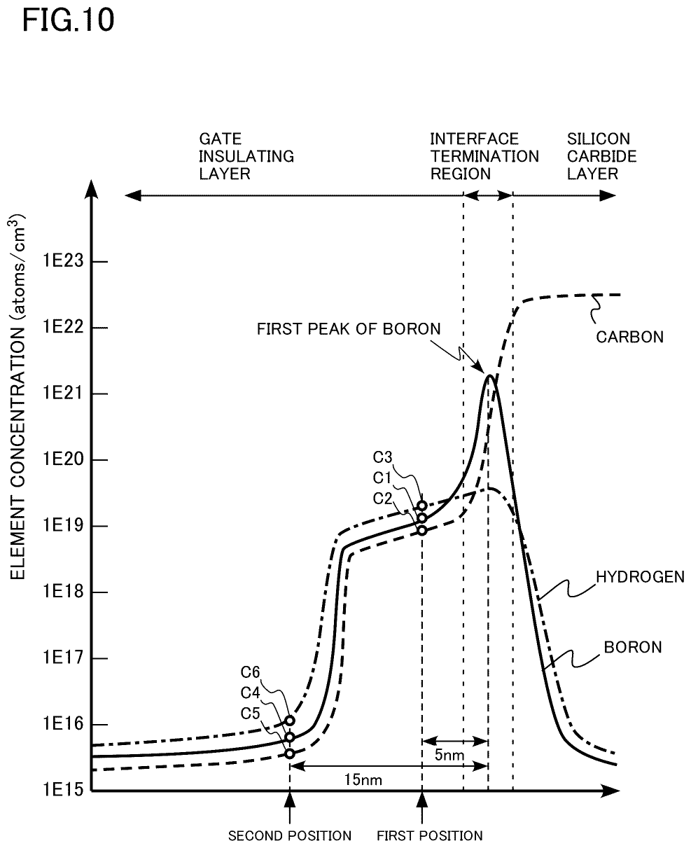

FIG. 10 is a graph illustrating element concentration distributions of the semiconductor device of the modified example of the first embodiment. FIG. 10 is a graph illustrating element concentration distributions in the gate insulating layer 28, the interface termination region 40, and the silicon carbide layer 10.

FIG. 10 illustrates concentration distributions of boron (B), carbon (C), and hydrogen (H). In FIG. 10, a solid line indicates the boron concentration distribution, a dotted line indicates the carbon concentration distribution, and an alternate long and short dash line indicates the hydrogen concentration distribution.

As illustrated in FIG. 10, for example, the fourth concentration (C4 in FIG. 10) of boron at the second position 15 nm away from the first peak of the boron concentration distribution toward the gate insulating layer 28 is less than 1×10¹⁷ cm⁻³. In addition, for example, the fifth concentration (C5 in FIG. 10) of carbon at the second position is less than 1×10¹⁷ cm⁻³. In addition, for example, the sixth concentration (C6 in FIG. 10) of hydrogen at the second position is less than 1×10¹⁷ cm⁻³.

For example, a MOSFET having the element concentration distributions as illustrated in FIG. 10 can be manufactured by additionally forming a silicon oxide film on the silicon oxide film containing boron after the second heat treatment in the manufacturing method of the first embodiment.

As described above, according to the first embodiment and the modified example, the method for manufacturing the semiconductor device in which the amount of the harmful defects in the gate insulating layer is reduced is achieved.

### Second Embodiment

A semiconductor device of a second embodiment is different from that of the first embodiment in terms of being a MOSFET of a trench gate type including a gate electrode in a trench. In addition, a difference from the first embodiment is that a surface of a silicon carbide layer facing the gate electrode is a face inclined at 0° or more and 8° or less with respect to a {1-100} face or a face inclined at 0° or more and 8° or less with respect to a {11-20} face. Hereinafter, some of the content overlapping with that in the first embodiment will not be described.

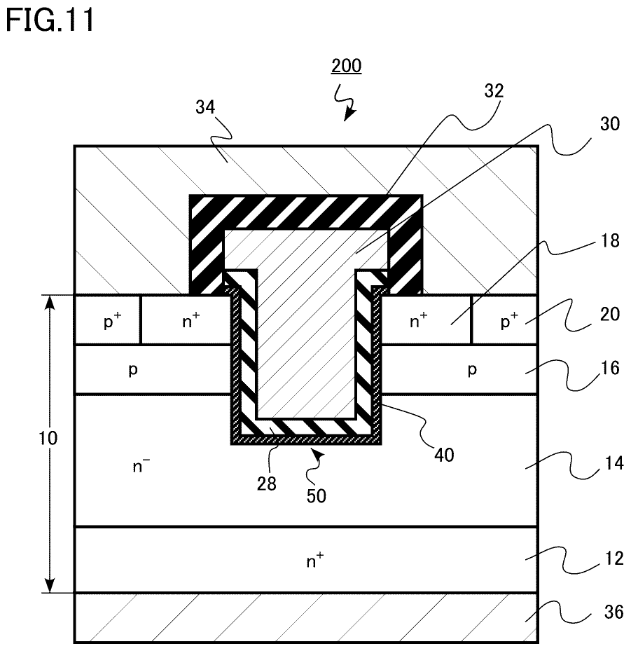

FIG. 11 is a schematic cross-sectional view of the semiconductor device of the second embodiment. The semiconductor device of the second embodiment is a MOSFET 200. The MOSFET 200 is the MOSFET of the trench gate type including the gate electrode in the trench. In addition, the MOSFET 200 is an n-channel MOSFET using electrons as carriers.

The MOSFET 200 includes the silicon carbide layer 10, the gate insulating layer 28 (silicon oxide layer), the gate electrode 30, the interlayer insulating film 32, the source electrode 34, the drain electrode 36, the interface termination region 40 (region), and a trench 50.

The silicon carbide layer 10 includes the drain region 12, the drift region 14, the p-well region 16, the source region 18, and the p-well contact region 20.

The trench 50 penetrates the source region 18 and the p-well region 16 and reaches the drift region 14. A bottom face of the trench 50 is disposed in the drift region 14.

The gate insulating layer 28 and the gate electrode 30 are provided in the trench 50. A side face of the trench 50 is, for example, a face having an off-angle of 0° or more and 8° or less with respect to an m-face, or a face having an off-angle of 0° or more and 8° or less with respect to an a-face.

On the side face of the trench 50, a surface of the silicon carbide layer 10 facing the gate electrode 30 is, for example, a face inclined at 0° or more and 8° or less with respect to the {1-100} face, or a face inclined at 0° or more and 8° or less with respect to the {11-20} face.

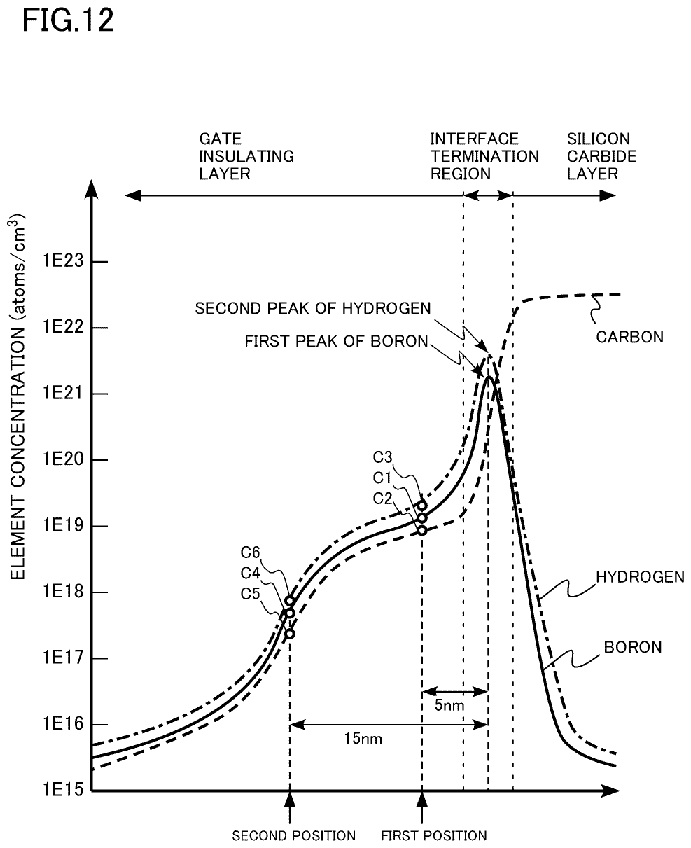

FIG. 12 is a graph illustrating element concentration distributions of the semiconductor device of the second embodiment. FIG. 12 is a graph illustrating the element concentration distributions in the gate insulating layer 28, the interface termination region 40, and the silicon carbide layer 10 on the side face of the trench 50.

FIG. 12 illustrates concentration distributions of boron (B), carbon (C), and hydrogen (H). In FIG. 12, a solid line indicates the boron concentration distribution, a dotted line indicates the carbon concentration distribution, and an alternate long and short dash line indicates the hydrogen concentration distribution.

The boron concentration distribution has a first peak in the interface termination region 40. The boron concentration at the first peak is, for example, 1×10²⁰ cm⁻³ or more and 1×10²² cm⁻³ or less. A full width at half maximum for the first peak of the boron concentration distribution is, for example, 1 nm or less. Boron is segregated at an interface between the silicon carbide layer 10 and the gate insulating layer 28.

The hydrogen concentration distribution has a second peak in the interface termination region 40. The hydrogen concentration at the second peak is, for example, 1×10²⁰ cm⁻³ or more and 1×10²² cm⁻³ or less. A full width at half maximum for the second peak of the hydrogen concentration distribution is, for example, 1 nm or less. Hydrogen is segregated at the interface between the silicon carbide layer 10 and the gate insulating layer 28. A hydrogen atom present in the interface termination region 40 is bonded to a carbon atom.

The hydrogen concentration at the second peak in the interface termination region 40 is higher than the boron concentration at the first peak of the interface termination region 40, for example.

According to the MOSFET 200 of the second embodiment, an amount of harmful defects in the gate insulating layer 28 is reduced, and a decrease in carrier mobility or a fluctuation in a threshold voltage can be suppressed as in the MOSFET 100 of the first embodiment.

When a MOSFET having a trench gate structure is formed using silicon carbide, there is a problem that the threshold voltage fluctuates due to AC stress. One factor is considered to be an interface state between the silicon carbide layer and the gate insulating layer. The interface state is considered to be generated particularly by dangling bonds of carbon present on an inner face of the trench. It is considered that, when the AC stress is applied, charge injected into the interface between the silicon carbide layer and the gate insulating layer is trapped in the interface state, and the threshold voltage fluctuates.

For example, when the inner face of the trench is the m-face or the a-face, the dangling bonds of carbon atoms are present on the outermost surface unlike a Si face.

In a method for manufacturing the MOSFET 200 of the second embodiment, a second heat treatment performed in an atmosphere containing hydrogen gas (H₂) is performed. As the second heat treatment is performed, the dangling bonds of the carbon atoms are terminated by hydrogen atoms. In the MOSFET 200 of the second embodiment, since the dangling bonds of the carbon atoms are terminated by the hydrogen atoms, the hydrogen concentration distribution has the peak in the interface termination region 40. In the MOSFET 200, the dangling bonds of the carbon atoms on the surface of the silicon carbide layer are reduced, and the fluctuation in the threshold voltage due to the AC stress of the MOSFET 200 can be suppressed.

As described above, according to the second embodiment, the semiconductor device and the method for manufacturing the semiconductor device in which the amount of the harmful defects in the gate insulating layer is reduced are achieved.

### Third Embodiment

An inverter circuit and a driving device of a third embodiment correspond to an inverter circuit and a driving device that includes the semiconductor device of the first embodiment.

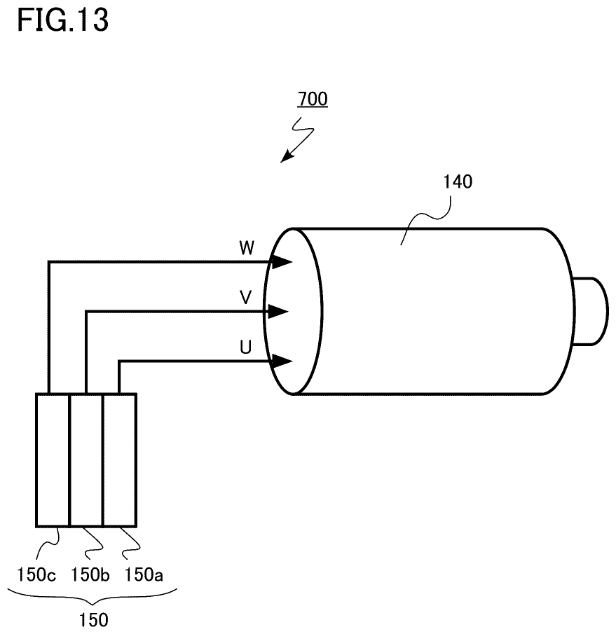

FIG. 13 is a schematic view of the driving device of the third embodiment. A driving device 700 includes a motor 140 and an inverter circuit 150.

The inverter circuit 150 includes three semiconductor modules 150a, 150b, and 150c using the MOSFET 100 of the first embodiment as a switching element. The three-phase inverter circuit 150 having three AC voltage output terminals U, V, and W is realized by connecting the three semiconductor modules 150a, 150b, and 150c in parallel. The motor 140 is driven by the AC voltage output from the inverter circuit 150.

According to the third embodiment, characteristics of the inverter circuit 150 and the driving device 700 are improved by providing the MOSFET 100 with improved characteristics.

### Fourth Embodiment

A vehicle of a fourth embodiment is a vehicle including the semiconductor device of the first embodiment.

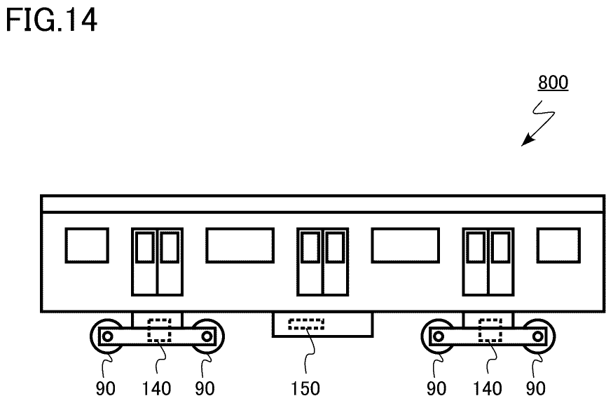

FIG. 14 is a schematic view of the vehicle of the fourth embodiment. A vehicle 800 of the fourth embodiment is a railway vehicle. The vehicle 800 includes the motor 140 and the inverter circuit 150.

The inverter circuit 150 includes three semiconductor modules using the MOSFET 100 of the first embodiment as a switching element. The three-phase inverter circuit 150 having three AC voltage output terminals U, V, and W is achieved by connecting the three semiconductor modules in parallel. The motor 140 is driven by the AC voltage output from the inverter circuit 150. Wheels 90 of the vehicle 800 are rotated by the motor 140.

According to the fourth embodiment, characteristics of the vehicle 800 are improved by providing the MOSFET 100 with improved characteristics.

### Fifth Embodiment

A vehicle of a fifth embodiment is a vehicle including the semiconductor device of the first embodiment.

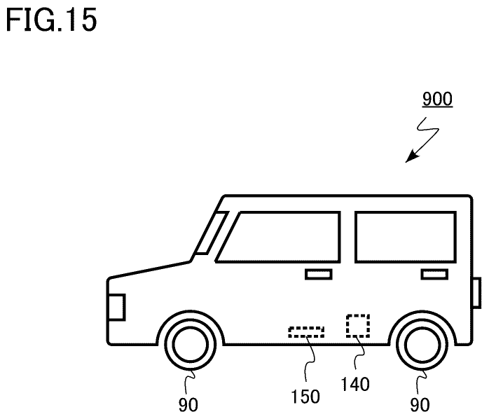

FIG. 15 is a schematic view of the vehicle of the fifth embodiment. A vehicle 900 of the fifth embodiment is a car. The vehicle 900 includes the motor 140 and the inverter circuit 150.

The inverter circuit 150 includes three semiconductor modules using the MOSFET 100 of the first embodiment as a switching element. The three-phase inverter circuit 150 having three AC voltage output terminals U, V, and W is achieved by connecting the three semiconductor modules in parallel.

The motor 140 is driven by the AC voltage output from the inverter circuit 150. Wheels 90 of the vehicle 900 are rotated by the motor 140.

According to the fifth embodiment, characteristics of the vehicle 900 are improved by providing the MOSFET 100 with improved characteristics.

### Sixth Embodiment

An elevator of a sixth embodiment is an elevator including the semiconductor device of the first embodiment.

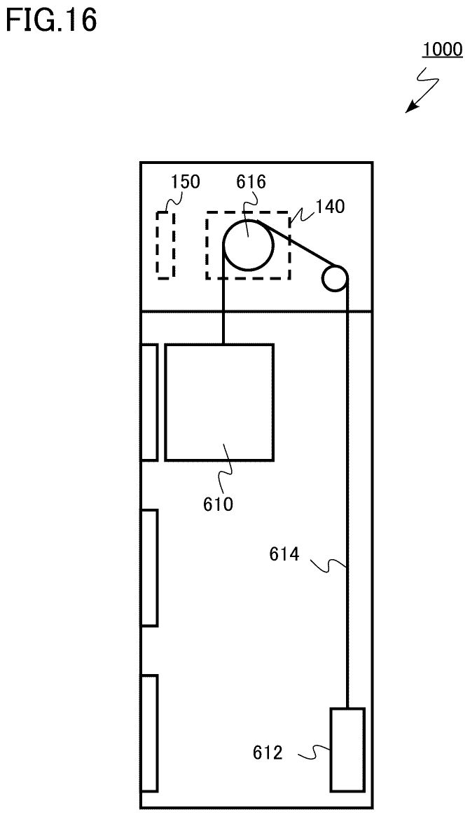

FIG. 16 is a schematic view of the elevator of the sixth embodiment. An elevator 1000 of the sixth embodiment includes an elevator car 610, a counterweight 612, a wire rope 614, a hoisting machine 616, the motor 140, and the inverter circuit 150.

The inverter circuit 150 includes three semiconductor modules using the MOSFET 100 of the first embodiment as a switching element. The three-phase inverter circuit 150 having three AC voltage output terminals U, V, and W is achieved by connecting the three semiconductor modules in parallel.

The motor 140 is driven by the AC voltage output from the inverter circuit 150. The hoisting machine 616 is rotated by the motor 140 to move the elevator car 610 up and down.

According to the sixth embodiment, characteristics of the elevator 1000 are improved by providing the MOSFET 100 with improved characteristics.

As described above, the description has been given in the first or second embodiment by exemplifying the case of 4H-SiC as the crystal structure of silicon carbide, but the present disclosure can also be applied to silicon carbide having other crystal structures such as 6H-SiC and 3C-SiC.

In addition, the present invention can also be applied to an n-channel insulated gate bipolar transistor (IGBT).

In addition, the present invention can be applied not only to the n-channel type but also to a MOSFET or an IGBT of a p-channel type.

In addition, the description has been given in the third to sixth embodiments by exemplifying the case where the semiconductor device of the present disclosure is applied to a vehicle or an elevator has been described as an example, but the semiconductor device of the present disclosure can also be applied to, for example, a power conditioner of a photovoltaic power generation system or the like.

In the first or second embodiment, the description has been given using hydrogen (H) as an example of one element selected from the group consisting of hydrogen (H), deuterium (D), and fluorine (F), but it is apparent from the result of the first principle calculation by the inventor that the same function and effect as those of hydrogen (H) can be obtained even in the case of deuterium (D) and fluorine (F).

When COB is subjected to a hydrogen treatment (deuterium treatment) with a hydrogen molecule (deuterium molecule), a COBH structure (COBD) is formed, and the COB is greatly stabilized. It is illustrated by the first principle calculation of the inventor that the energy thereof is as very large as 7.8 eV for each hydrogen (deuterium) atom constituting the hydrogen molecule (deuterium molecule). Hydrogen and deuterium have the same electronic state, and thus have equivalent stabilization energy.

COB+½·H₂ (D₂)=COBH+7.8 eV

Similarly, when COB is subjected to a fluorine treatment with a fluorine molecule, a COBF structure is formed and is greatly stabilized. It is illustrated by the first principle calculation of the inventor that the energy thereof is larger as 10.5 eV for each fluorine atom constituting the fluorine molecule.

COB+½·F₂=COBF+10.5 eV

That is, the COB structure can be greatly stabilized in terms of energy by the hydrogen treatment with the hydrogen molecule (H₂), the deuterium treatment with the deuterium (D₂) molecule, and the fluorine treatment with the fluorine (F₂) molecule, and if being formed, is not decomposed again to form a trap during device operation.

Although the case where the semiconductor device of the first embodiment is applied has been described as an example in the third to sixth embodiments, the semiconductor device of the second embodiment can also be applied, for example.

While certain embodiments have been described, these embodiments have been presented by way of example only, and are not intended to limit the scope of the inventions. Indeed, the semiconductor device, the inverter circuit, the driving device, the vehicle, and the elevator described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a silicon carbide layer;
a gate electrode;
a silicon oxide layer provided between the silicon carbide layer and the gate electrode and containing, boron (B), carbon (C), and one element selected from a group consisting of hydrogen (H), deuterium (D), and fluorine (F); and
a region provided between the silicon carbide layer and the silicon oxide layer and having a boron concentration equal to or more than 1×10²⁰ cm⁻³,
wherein a boron concentration distribution in the silicon carbide layer, the silicon oxide layer, and the region has a first peak in the region,
a first concentration of boron at a first position 5 nm away from the first peak toward the silicon oxide layer is equal to or more than 1×10¹⁸ cm⁻³,
a second concentration of carbon at the first position is equal to or more than 1×10¹⁸ cm⁻³,
a third concentration of the element at the first position is equal to or more than 1×10¹⁸ cm⁻³,
the second concentration is 80% or more and 120% or less of the first concentration, and
the third concentration is 80% or more and 120% or less of the first concentration.

2. The semiconductor device according to claim 1, wherein
a fourth concentration of boron at a second position 15 nm away from the first peak toward the silicon oxide layer is equal to or more than 1×10¹⁷ cm⁻³,
a fifth concentration of carbon at the second position is equal to or more than 1×10¹⁷ cm⁻³,
a sixth concentration of the element at the second position is equal to or more than 1×10¹⁷ cm⁻³,
the fifth concentration is 80% or more and 120% or less of the fourth concentration, and
the sixth concentration is 80% or more and 120% or less of the fourth concentration.

3. The semiconductor device according to claim 1, wherein
a fourth concentration of boron at a second position 15 nm away from the first peak toward the silicon oxide layer is less than 1×10¹⁷ cm⁻³,
a fifth concentration of carbon at the second position is less than 1×10¹⁷ cm⁻³, and
a sixth concentration of the element at the second position is less than 1×10¹⁷ cm⁻³.

4. The semiconductor device according to claim 1, wherein a surface of the silicon carbide layer facing the gate electrode is a face inclined at 0° or more and 8° or less with respect to a {0001} face, and a concentration of the element in the region is 1×10²⁰ cm⁻³ or less.

5. The semiconductor device according to claim 1, wherein a surface of the silicon carbide layer facing the gate electrode is a face inclined at 0° or more and 8° or less with respect to a {1-100} face or a face inclined at 0° or more and 8° or less with respect to a {11-20} face, and a concentration distribution of the element in the region has a second peak in the region.

6. The semiconductor device according to claim 5, wherein a concentration of the element at the second peak is higher than a concentration of boron at the first peak.

7. The semiconductor device according to claim 1, wherein the silicon oxide layer contains a boron atom bonded to three oxygen atoms and the element.

8. The semiconductor device according to claim 7, wherein, when the silicon oxide layer contains a boron atom bonded to four oxygen atoms, an amount of the boron atom bonded to the three oxygen atoms and the element in the silicon oxide layer is larger than an amount of the boron atom bonded to the four oxygen atoms.

9. The semiconductor device according to claim 8, wherein, in the silicon oxide layer, the amount of the boron atom bonded to the three oxygen atoms and the element is ten times or more the amount of the boron atom bonded to the four oxygen atoms.

10. The semiconductor device according to claim 1, wherein the region contains a boron atom bonded to three carbon atoms.

11. A semiconductor device comprising:
a silicon carbide layer;
a gate electrode;
a silicon oxide layer provided between the silicon carbide layer and the gate electrode and containing boron (B), carbon (C), and one element selected from a group consisting of hydrogen (H), deuterium (D), and fluorine (F); and
a region provided between the silicon carbide layer and the silicon oxide layer and having a boron concentration equal to or more than 1×10²⁰ cm⁻³,
wherein the silicon oxide layer contains a boron atom bonded to three oxygen atoms and the element.

12. The semiconductor device according to claim 11, wherein a concentration of boron, a concentration of carbon, and a concentration of the element in the silicon oxide layer are 1×10¹⁸ cm⁻³ or more.

13. The semiconductor device according to claim 11, wherein, when the silicon oxide layer contains a boron atom bonded to four oxygen atoms, an amount of the boron atom bonded to the three oxygen atoms and the element in the silicon oxide layer is larger than an amount of the boron atom bonded to the four oxygen atoms.

14. The semiconductor device according to claim 13, wherein, in the silicon oxide layer, the amount of the boron atom bonded to the three oxygen atoms and the element is ten times or more the amount of the boron atom bonded to the four oxygen atoms.

15. The semiconductor device according to claim 11, wherein the region contains a boron atom bonded to three carbon atoms.

16. The semiconductor device according to claim 1, wherein a fluctuation in a threshold voltage is less than 0.1 V when AC stress of −5 MV/cm to 5 MV/cm at 1 MHz is applied between the silicon carbide layer and the gate electrode for 100 hours.

17. An inverter circuit comprising the semiconductor device according to claim 1.

18. A driving device comprising the semiconductor device according to claim 1.

19. A vehicle comprising the semiconductor device according to claim 1.

20. An elevator comprising the semiconductor device according to claim 1.
